(19) United States
(12) Patent Application Publication
(10) Pub. No.: US 2022/0352899 A1
(43) Pub. Date: Nov. 3, 2022

(54) DATA-DEPENDENT CLOCK-GATING SWITCH DRIVER FOR A DIGITAL-TO-ANALOG CONVERTER (DAC)

(71) Applicant: QUALCOMM Incorporated, San Diego, CA (US)

(72) Inventors: Nitz SAPUTRA, Burlingame, CA (US); Ashok SWAMINATHAN, Cardiff, CA (US); Andrew WEIL, San Diego, CA (US)

(21) Appl. No.: 17/244,384

(22) Filed: Apr. 29, 2021

(51) Int. Cl. H03M 1/66; H03K 19/21; H04B 1/00

(52) U.S. Cl. CPC H03M 1/662; H03K 19/21; H04B 1/0003

(57) ABSTRACT

Certain aspects of the present disclosure provide a digital-to-analog conversion circuit. The digital-to-analog conversion circuit generally includes a detection circuit configured to detect digital transitions in a digital input signal. The digital-to-analog conversion circuit also includes a clock-gating circuit having an input coupled to an output of the detection circuit. The clock-gating circuit is configured to gate a clock signal for the digital-to-analog conversion circuit based on an output signal from the detection circuit.

### BACKGROUND

### Field of the Disclosure

Certain aspects of the present disclosure generally relate to electronic components and, more particularly, to circuitry for digital-to-analog conversion.

### Description of Related Art

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of sᵤₚporting communication with multiple users by sharing the available system resources (e.g., time, frequency, and power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system).

Wireless communication devices may include one or more transmitters associated with one or more antennas for transmitting radio frequency (RF) signals. Wireless communication devices may also include one or more receivers associated with the same or one or more other antennas for receiving RF signals. A transmitter may include a digital-to-analog converter (DAC) configured to convert signals from the digital domain to the analog domain for further processing (e.g., filtering, upconverting, and amplification) prior to transmission.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide the advantages described herein.

Certain aspects of the present disclosure provide a digital-to-analog conversion circuit. The digital-to-analog conversion circuit generally includes a detection circuit configured to detect digital transitions in a digital input signal. The digital-to-analog conversion circuit also includes a clock-gating circuit having an input coupled to an output of the detection circuit and configured to gate a clock signal for the digital-to-analog conversion circuit based on an output signal from the detection circuit.

Certain aspects of the present disclosure provide a wireless device. The wireless device includes at least one antenna, a digital-to-analog conversion circuit, and a transmit path coupled between an output of the digital-to-analog conversion circuit and the at least one antenna. The digital-to-analog conversion circuit generally includes a detection circuit configured to detect digital transitions in a digital input signal. The digital-to-analog conversion circuit also includes a clock-gating circuit having an input coupled to an output of the detection circuit and configured to gate a clock signal for the digital-to-analog conversion circuit based on an output signal from the detection circuit.

Certain aspects of the present disclosure provide a method for digital-to-analog conversion. The method generally includes receiving a digital input signal and determining whether there is a digital transition in the digital input signal. The method also includes gating a clock signal for a digital-to-analog conversion circuit based on the determination.

Certain aspects of the present disclosure provide an apparatus for digital-to-analog conversion. The apparatus generally includes means for receiving a digital input signal, means for determining whether there is a digital transition in the digital input signal, and means for gating a clock signal to the apparatus based on the determination.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a diagram of an example wireless communications network, in which certain aspects of the present disclosure may be practiced.

FIG. 2 is a block diagram of an example access point (AP) and example user terminals, in which certain aspects of the present disclosure may be practiced.

FIG. 3 is a block diagram of an example transceiver front end, in which certain aspects of the present disclosure may be practiced.

FIG. 4 illustrates an example current-steering digital-to-analog converter (DAC), in which certain aspects of the present disclosure may be practiced.

FIG. 5 illustrates an example implementation of a switch driver for the current-steering DAC of FIG. 4.

FIG. 6 is a block diagram of an example data-dependent clock-gating switch driver, in accordance with certain aspects of the present disclosure.

FIG. 7 illustrates an example circuit for implementing the data-dependent clock-gating switch driver of FIG. 6, in accordance with certain aspects of the present disclosure.

FIG. 8 illustrates another example circuit for implementing the data-dependent clock-gating switch driver of FIG. 6, in accordance with certain aspects of the present disclosure.

FIG. 9 illustrates an example implementation of the data-dependent clock-gating switch driver of FIG. 7, in accordance with certain aspects of the present disclosure.

FIG. 10 illustrates a circuit for another example data-dependent clock-gating switch driver, in accordance with certain aspects of the present disclosure.

FIG. 11 illustrates an example interleaved digital-to-analog converter circuit, in accordance with certain aspects of the present disclosure.

FIG. 12 is a flow diagram of example operations for digital-to-analog conversion, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to techniques and apparatus for digital-to-analog conversion. More particularly, certain aspects provide a digital-to-analog conversion circuit including switch drivers that may be selectively clock gated to reduce the power consumption of the switch drivers. For example, a digital-to-analog converter (DAC) can include a large number of switch drivers. In certain applications, a significant amount of the power may be consumed by the clock buffer inside each switch driver, but a fraction of the switch drivers may change their state on any given clock transition. As a result, the power consumed by the clock buffers may be wasted.

As described in more detail herein, in some aspects, a detection circuit may be used to detect digital transitions in a digital input signal, and a clock-gating circuit may be used to gate a clock signal for the switch driver, based on an output signal from the detection circuit. For example, the clock-gating circuit may be used to gate the clock signal for the switch driver when a digital transition in the digital input signal is not detected. By gating the clock signal when there is no data transition for each switch driver, aspects can significantly reduce the switch driver's power consumption, and in turn the power consumption of the DAC.

### EXAMPLE WIRELESS COMMUNICATIONS

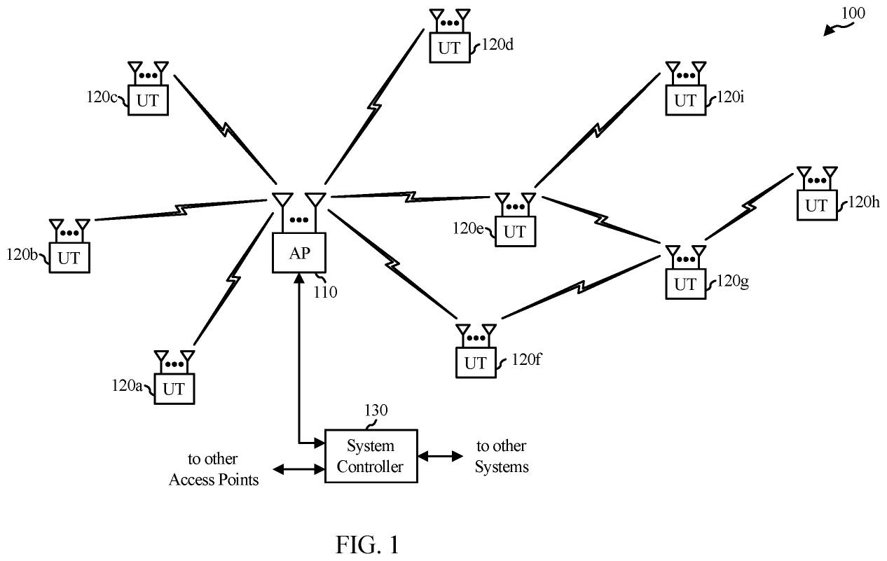

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), a next generation Node B (gNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., to keep costs down) or multiple antennas (e.g., where the additional cost can be sᵤₚported). In some aspects, the user terminal 120 or access point 110 may include a digital-to-analog converter (DAC) implemented with circuitry configured to clock gate each switch driver of the DAC based on whether a transition in an input signal to the switch driver is detected, as described in more detail herein.

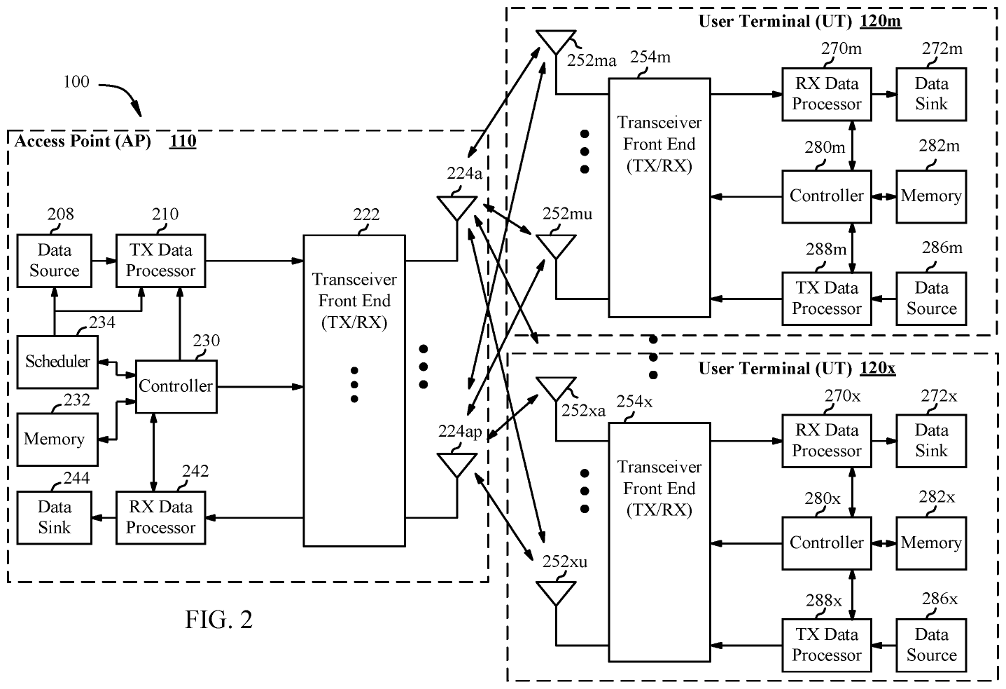

FIG. 2 shows a block diagram of access point 110 and two user terminals 120m and 120x in the wireless communications system 100. Access point 110 is equipped with Nₐₚ antennas 224a through 224ap. User terminal 120m is equipped with N_{ut, m} antennas 252ma through 252mu, and user terminal 120x is equipped with N_{ut, x}antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering, beamforming, or some other spatial processing technique may be used at the access point and/or user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ}for one of the N_{ut, m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut, m} antennas for transmit diversity via an RF switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut, m}antennas 252 receive the downlink signals from access point 110. For receive diversity at the user terminal 120, the transceiver front end 254 may select signals received from one or more of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal. In some aspects, the transceiver front end 254 or 222 may include a DAC implemented with circuitry configured to clock gate each switch driver of the DAC based on whether a transition in an input signal to the switch driver is detected, as described in more detail herein.

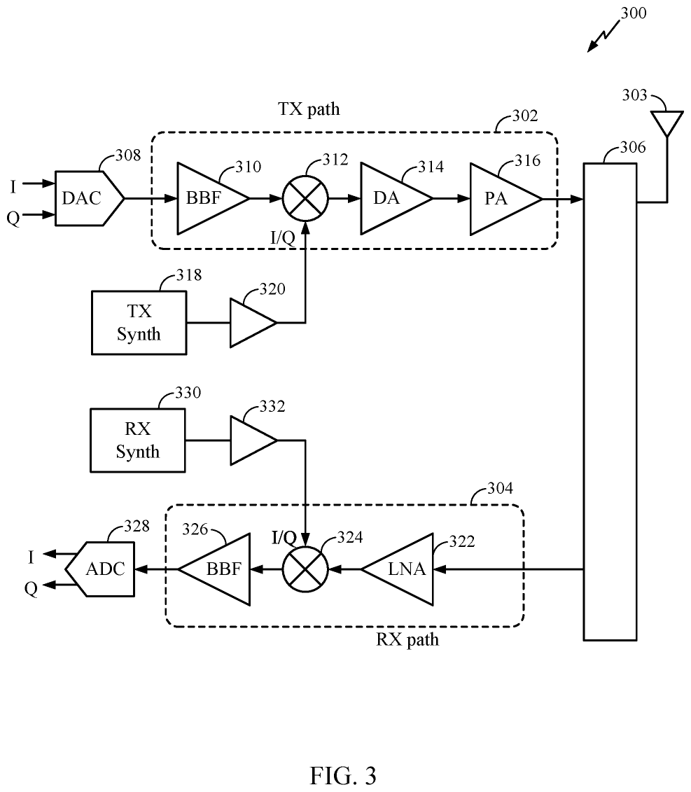

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a “transmit chain”) for transmitting signals via one or more antennas and a receive (RX) path 304 (also known as a “receive chain”) for receiving signals via the antennas. When the TX path 302 and the RX path 304 share an antenna 303, the paths may be connected with the antenna via an interface 306.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The DAC 308 (also referred to as a “transmitter DAC” or “TX DAC”) may include circuitry configured to clock gate each switch driver of the DAC based on whether a transition in an input signal to the switch driver is detected, as described in more detail herein. The BBF 310, the mixer 312, and the DA 314 may be included in a radio frequency integrated circuit (RFIC), while the PA 316 may be external to the RFIC.

The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I and Q signals for digital signal processing.

While it is desirable for the output of an LO to remain stable in frequency, tuning the LO to different frequencies typically entails using a variable-frequency oscillator, which may involve compromises between stability and tunability. Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324.

While FIGS. 1-3 provide a wireless communication system as an example application in which certain aspects of the present disclosure may be implemented to facilitate understanding, certain aspects described herein may be used for digital-to-analog conversion in any of various other suitable systems (e.g., any electronic system).

### EXAMPLE TECHNIQUES FOR DIGITAL-TO-ANALOG CONVERSION

Current-steering DACs are one example architecture for high performance digital-to-analog conversion in many wireless transmitters. Current-steering DACs offer versatility of design, high speed operation, and high performance.

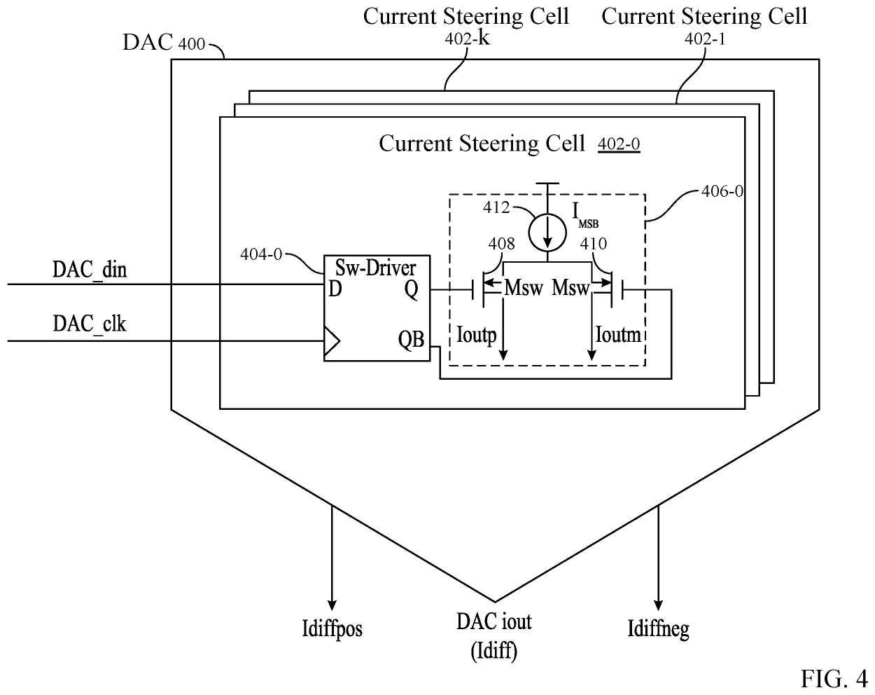

FIG. 4 illustrates an example current-steering DAC 400 (e.g., implemented as the DAC 308 of FIG. 3). The DAC 400 includes current-steering cells 402-0 through 402-k. Each current-steering cell 402 includes a switch driver 404 and a differential current switching circuit 406 (also referred to as a current-steering circuit). The switch driver 404 may generally be used to improve the dynamic performance of the current-steering DAC 400. For example, the switch driver 404 can be used to reduce the signal feed-through, reduce current source node setting, reduce local and global timing errors, etc. As shown, the switch driver 404 may be implemented by a delay (D) flip-flop or latch. The differential current switching circuit 406 includes a current source 412 and current-steering switches 408 and 410. As illustrated, each of the current-steering switches may be implemented using a p-type metal-oxide-semiconductor (PMOS) transistor or other p-type transistor.

The switch driver 404 may receive a digital input signal (DAC_din) and an input clock signal (DAC_clk) and may generate an output signal (Q) and a complementary output signal (QB). The two output signals (Q/QB) of the switch driver 404 may be used to drive the current-steering switches 408 and 410 of the differential current switching circuit 406. For example, the output signal (Q) may be used to drive a gate of the PMOS transistor used to implement the current-steering switch 408, and the complementary output signal (QB) may be used to drive a gate of the PMOS transistor used to implement the current-steering switch 410.

Depending on a digital input code (DAC_din), each bit of the DAC 400 associated with a current-steering cell 402 may source a positive current (e.g., Ioutp 0 to Ioutp k, k being an integer greater than 1, where k+1 is the number of cells) or a negative current (e.g., Ioutm 0 to Ioutm k) to respective outputs depending on the logic level for a respective bit of the digital input code. A “positive current” from a current-steering cell generally refers to a current sourced to a positive output node (e.g., a positive ladder node of a resistor ladder circuit), and a “negative current” from a current-steering cell generally refers to a current sourced to a negative output node (e.g., a negative ladder node of the resistor ladder circuit). The current-steering switches 408 and 410 of each current-steering cell 402 may selectively provide a respective one of Ioutp 0 to Ioutp k or a respective one of Ioutm 0 to Ioutm k.

The positive currents (Ioutp 0 to Ioutp k) from the current-steering cells 402 contribute mostly to a positive portion (Idiffpos) of a differential output current (DAC iout), and the negative currents (Ioutm 0 to Ioutm k) contribute mostly to a negative portion (Idiffneg) of the differential output current (DAC iout). In some cases, the current contributions to Idiffpos and Idiffneg may be summed (e.g., via a summing circuit or at a summing node, not shown in FIG. 4) to generate the differential output current (DAC iout).

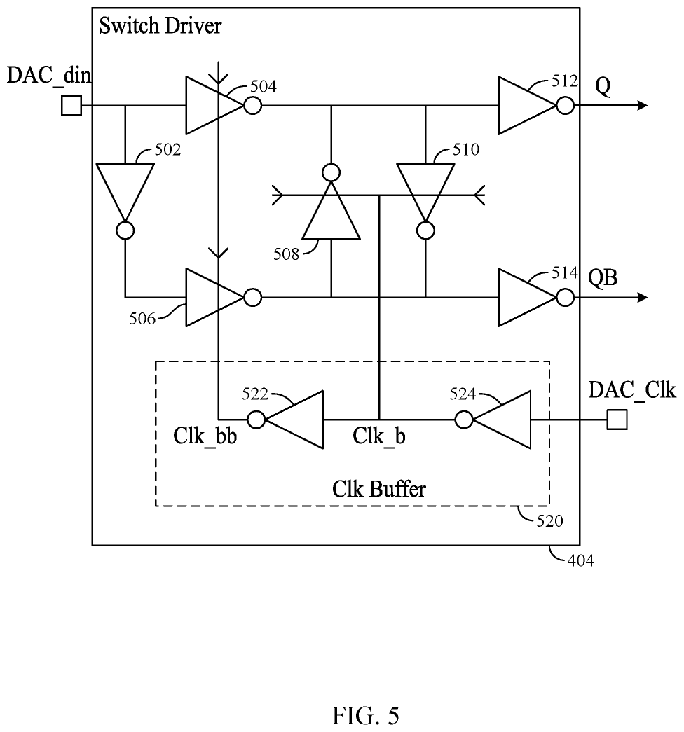

FIG. 5 illustrates an example implementation of a switch driver (e.g., switch driver 404) of a current-steering cell (e.g., current-steering cell 402). The switch driver is implemented by a D latch, as described above, with data input signal (DAC_din), clock input signal (DAC_Clk), and complementary output signals (Q and QB). As shown, the switch driver 404 includes inverters 502, 504, 506, 508, 510, 512, 514 and a clock buffer 520. The clock buffer 520 includes inverters 522 and 524. The inverters 504, 506, 508, and 510 may be tri-state inverters (also referred to as tri-state buffers). The inverter 524 may generate an inverted clock signal (Clk_b) based on the clock input signal (DAC_Clk), and the inverter 522 may generate a twice-inverted clock signal (Clk_bb) based on the inverted clock signal (Clk_b). The inverters 508 and 510 may be tri-stated with the inverted clock signal (Clk_b), and the inverters 504 and 506 may be tri-stated with the twice-inverted clock signal (Clk_bb).

In FIG. 5, the inverter 502 may generate the complementary signal of DAC_din to the inverter 506. The DAC_din and the complementary DAC_din are clocked by Clk_bb at the inverters 504 and 506, respectively, such that once the complementary signals pass through the inverters 504 and 512 and inverters 506 and 514, the output Q and complementary output QB are realized according to DAC_Clk.

One issue with the architecture of the DAC 400 is that the switch driver 404 can cause the DAC to consume a significant amount of power in certain applications. For example, for 5G wireless applications, the DAC 400 may operate at a high frequency (e.g., 2 to 3 GHz or greater), significantly increasing the power consumption of the data path, which can include a large number (e.g., 100 or greater) of switch drivers 404.

As shown in FIG. 5, because the clock buffer 520 may be operating at the clock frequency (e.g., based on DAC_Clk), a significant amount of the power consumption may be due to power consumed by the clock buffer 520. However, because a subset of the switch drivers 404 may change state on any given clock transition, the power consumed by the clock buffers 520 may be wasted. In other words, when DAC_din stays the same, the switch driver need not be clocked again to maintain the same output state.

### EXAMPLE DATA-DEPENDENT CLOCK-GATING SWITCH DRIVER FOR DIGITAL-TO-ANALOG CONVERSION

Certain aspects of the present disclosure provide techniques for implementing a data-dependent clock-gating switch driver for a DAC. As described below, aspects can significantly reduce the switch driver power consumption by gating the clock for each switch driver when there is no data transition for that driver.

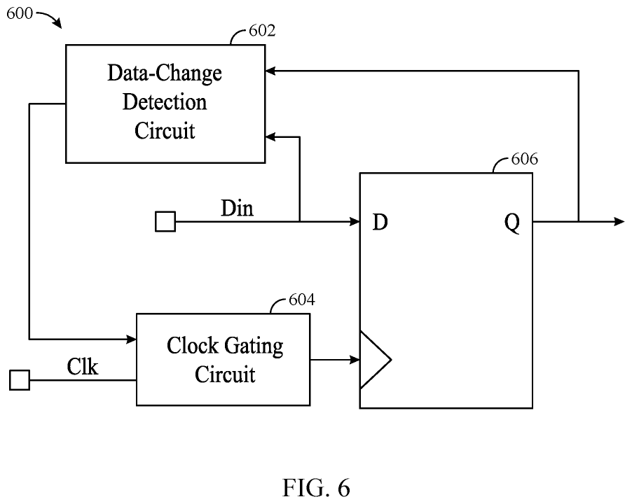

FIG. 6 is a block diagram of an example data-dependent clock-gating switch driver 600, in accordance with certain aspects of the present disclosure. In some aspects, the data-dependent clock-gating switch driver 600 may be implemented as part of a DAC (e.g., DAC 400). For example, the data-dependent clock-gating switch driver 600 may be implemented as part of a current-steering cell (e.g., current-steering cell 402) of a DAC and, in some instances, may replace the switch driver (e.g., switch driver 404) in the current-steering cell. The data-dependent clock-gating switch driver 600 includes a data-change detection circuit 602, a clock-gating circuit 604, and a switch driver 606.

The data-change detection circuit 602 has an input coupled to the input of the switch driver 606 and another input coupled to the output of the switch driver 606. The data-change detection circuit 602 is configured to detect digital transitions in the digital input signal (Din), for example, by comparing the signals at the input and output of the switch driver 606.

The clock-gating circuit 604 has an input coupled to the output of the data-change detection circuit 602, another input configured to receive a clock signal (Clk), and an output coupled to the clock input of the switch driver 606. The clock-gating circuit 604 is configured to gate the clock of the switch driver, based on the output from the data-change detection circuit 602. For example, the clock-gating circuit 604 may allow the clock signal (Clk) to clock the switch driver 606 when a digital transition in the digital input signal (Din) is detected by the data-change detection circuit 602. The clock-gating circuit 604 may block the clock signal (Clk) from clocking the switch driver 606 when no digital transition in the digital input signal (Din) is detected by the data-change detection circuit 602. By gating the clock of the switch driver when there is no data transition in the data input signal, aspects can significantly reduce power consumption of the switch driver 606.

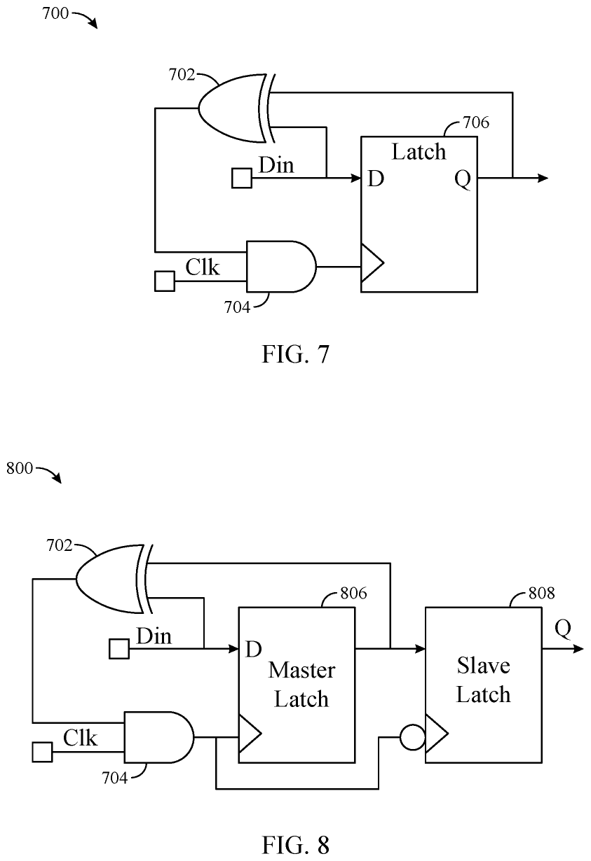

FIG. 7 illustrates a circuit 700 for an example data-dependent clock-gating switch driver, in accordance with certain aspects of the present disclosure. The circuit 700 may be used to implement the data-dependent clock-gating switch driver 600 of FIG. 6. Here, the circuit 700 includes an exclusive OR (XOR) logic gate 702, an AND logic gate 704, and a data latch 706. The XOR logic gate 702 may be used to implement the data-change detection circuit 602, the AND logic gate 704 may be used to implement the clock-gating circuit 604, and the latch 706 may be used to implement the switch driver 606.

As shown, the AND logic gate 704 has (i) a first input coupled to a clock signal node configured to receive the clock signal (Clk) and (ii) a second input coupled to the output of the XOR logic gate 702. The XOR logic gate 702 has (i) a first input coupled to a data output (Q) of the latch 706, (ii) a second input coupled to a data input (Din) of the latch 706, and (iii) an output coupled to the second input of the AND logic gate 704.

FIG. 8 illustrates a circuit 800 for an example data-dependent clock-gating switch driver, in accordance with certain aspects of the present disclosure. The circuit 800 may be used to implement the data-dependent clock-gating switch driver 600 of FIG. 6. Compared to circuit 700, here the circuit 800 includes a D flip-flop with primary and secondary latches 806 and 808 (also known as a master-slave D flip-flop) that may be used to implement the switch driver 606.

As shown, the AND logic gate 704 has (i) a first input coupled to a clock signal node configured to receive the clock signal (Clk) and (ii) a second input coupled to the output of the XOR logic gate 702. The XOR logic gate 702 has (i) a first input coupled to a data output of the primary latch 806, (ii) a second input coupled to a data input (Din) of the primary latch 806, and (iii) an output coupled to the second input of the AND logic gate 704.

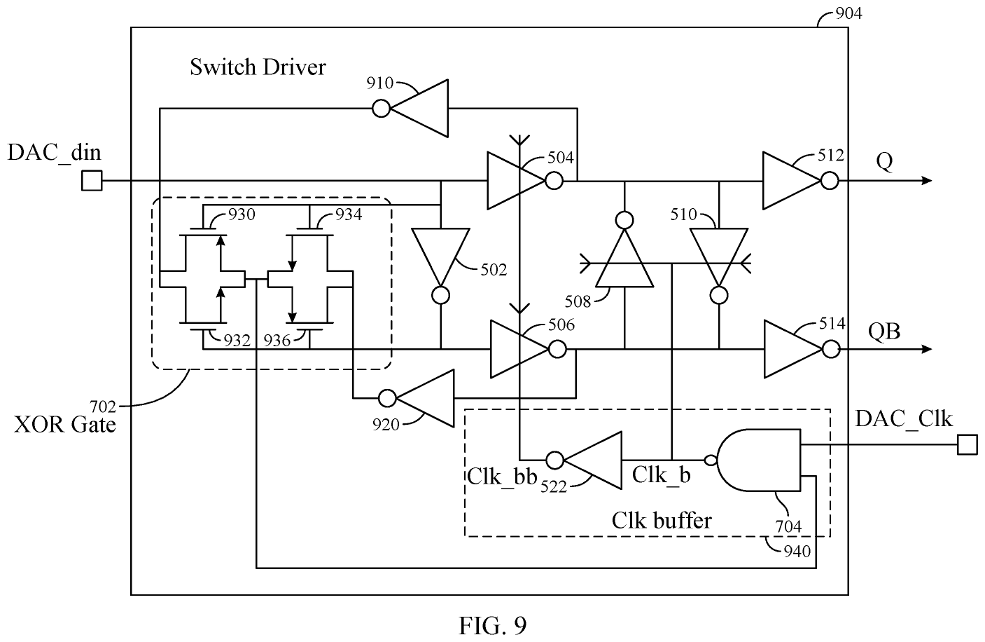

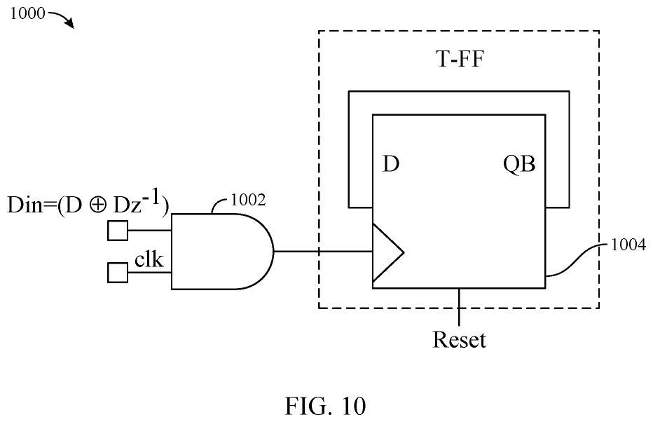

FIG. 9 illustrates an example implementation of a data-dependent clock-gating switch driver 904 for a current-steering cell (e.g., current-steering cell 402), in accordance with certain aspects of the present disclosure. Compared to the switch driver 404 illustrated in FIG. 5, the switch driver 904 includes inverters 502, 504, 506, 508, 510, 512, 514, a clock buffer 940, an XOR logic gate 702, and inverters 910 and 920. The clock buffer 940 includes an AND logic gate 704.

The XOR logic gate 702 can be implemented using differential transmission gates to provide balanced loading between the Q and QB signal paths. As shown, the XOR logic gate 702 can be implemented with a buffered passgate topology using p-type transistors 930, 936 and n-type transistors 932, 934. The inputs of the XOR logic gate 702 may also be coupled to outputs of inverter 910 and inverter 920 to receive buffered copies of Q and QB, respectively. The buffered copies of Q and QB can help to avoid a timing disturbance on the sensitive outputs.

FIG. 10 illustrates a circuit 1000 for an example data-dependent clock-gating switch driver, in accordance with certain aspects of the present disclosure. The circuit 1000 may be used to implement an alternative to the block diagram of the data-dependent clock-gating switch driver 600 using toggle (T) flip-flops in the switch drivers. Here, the circuit 1000 includes an AND logic gate 1002 and a T flip-flop 1004. The T flip-flop 1004 has a complementary data output (QB) that is coupled to a data input of the T flip-flop 1004. The T flip-flop 1004 can be used in place of the switch driver 606 where its output toggles on each rising (or on each falling) clock edge. In this implementation, the XOR logic gate may be implemented as part of the data encoder (e.g., outside the switch driver, such as in the TX data processor 288 of FIG. 2). For example, the input data (Din=(D XOR D z⁻¹)) is representative of the XOR'ed data of the current data input with the previous data input.). Additionally, in this implementation, the clock may be gated when the input data (Din) is “low.” A reset signal may be provided for initialization of the T flip-flop 1004.

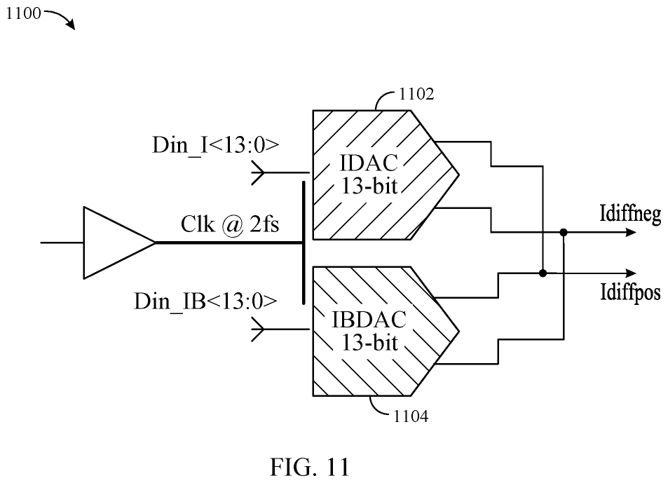

In some aspects, the DAC circuit (e.g., DAC 308) may be implemented as an interleaved DAC. FIG. 11, for example, illustrates an interleaved DAC circuit 1100 with a first DAC 1102 and a second DAC 1104, in accordance with certain aspects of the present disclosure. In some cases, an interleaved DAC may operate using two clocks with opposite phases at the sampling frequency (fs). However, any timing skew between the two clocks for the two DACs can compromise the image rejection and may involve complex timing calibration to correct.

In other cases, as illustrated in FIG. 11, the interleaved DAC circuit 1100 may use a single clock frequency for the first DAC 1102 and the second DAC 1104 that is two times the sampling frequency (2fs) in order to avoid the timing skew and timing calibration. Operating with a clock at 2fs could have a significant power penalty compared to running two clocks at fs. In some aspects, the data-dependent clock-gating switch driver described herein may allow the interleaved DAC circuit 1100 to run the clock frequency at 2fs with a reduced power penalty on the switch drivers. This power savings in the switch drivers that are not transitioning can alleviate the additional power consumed in the clock buffers by the higher clock frequency.

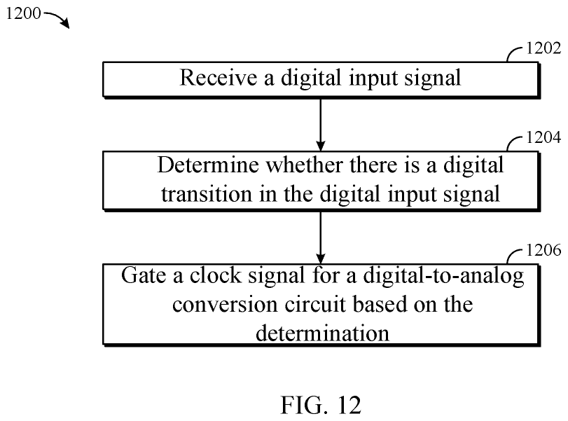

FIG. 12 is a flow diagram of example operations 1200 for digital-to-analog conversion, in accordance with certain aspects of the present disclosure. The operations 1200 may be performed by a digital-to-analog conversion circuit (e.g., DAC 308 or 400).

The operations 1200 may begin, at block 1202, by receiving a digital input signal. At block 1204, the digital-to-analog conversion circuit may determine whether there is a digital transition in the digital input signal. At block 1206, the digital-to-analog conversion circuit may gate a clock signal for the digital-to-analog conversion circuit based on the determination.

In some aspects, the digital-to-analog conversion circuit may include a switch driver (e.g., switch driver 404). In this case, the operations 1200 may further include generating, via the switch driver, a digital output signal based on the digital input signal. Also, in this case, determining whether there is a digital transition (at block 1204) may include comparing, via a first circuit (e.g., data-change detection circuit 602), the digital input signal to the digital output signal. Additionally, gating the clock signal (at block 1206) may include blocking, via a second circuit (e.g., clock-gating circuit 604), the clock signal from clocking the switch driver when the determination is that there is no digital transition in the digital input signal.

In some aspects, the first circuit may include an XOR logic gate (e.g., XOR logic gate 702) having a first input coupled to a data output of the switch driver and (ii) a second input coupled to a data input of the switch driver. The second circuit may include an AND logic gate (e.g., AND logic gate 704) having (i) a first input coupled to a clock signal node configured to receive the clock signal, (ii) a second input coupled to an output of the XOR logic gate, and (iii) an output coupled to a clock input of the switch driver.

In some aspects, the digital-to-analog conversion circuit may include a plurality of current-steering cells (e.g., current-steering cells 402-0 to 402-k). Each current-steering cell may include a current-steering circuit (e.g., differential current switching circuit 406) and a switch driver (e.g., switch driver 404) coupled to the current-steering circuit.

In these aspects, determining whether there is a digital transition in the digital input signal (at block 1204) may include comparing, via a first circuit (e.g., data-change detection circuit 602), an input signal to the respective switch driver to an output signal from the respective switch driver. Additionally, gating the clock signal (at block 1206) may include blocking, via a second circuit (e.g., clock-gating circuit 604), the clock signal from clocking the respective switch driver when the determination is that there is no digital transition in the digital input signal. In one aspect, the operations 1200 may further include allowing, via the second circuit, the clock signal to clock the respective switch driver when the determination is that there is a digital transition in the digital input signal. An output of the second circuit may be coupled to a clock input of the respective switch driver.

In aspects where the digital-to-analog conversion circuit may include a plurality of current-steering cells, the first circuit may include an XOR logic gate (e.g., XOR logic gate 702) having (i) a first input coupled to a data output of the respective switch driver and (ii) a second input coupled to a data input of the respective switch driver. The second circuit may include an AND logic gate (e.g., AND logic gate 704) having (i) a first input coupled to a clock signal node configured to receive the clock signal, (ii) a second input coupled to an output of the XOR logic gate, and (iii) an output coupled to a clock input of the respective switch driver.

In one aspect, the respective switch driver may include a T flip-flop (e.g., T flip-flop 1004), where a data output of the T flip-flop is coupled to a data input of the T flip-flop. In one aspect, the respective switch driver may include a delay flip-flop.

In some aspects, the digital-to-analog conversion circuit may include an interleaved digital-to-analog conversion circuit (e.g., interleaved DAC circuit 1100) comprising a first DAC (e.g., DAC 1102) and a second DAC (e.g., DAC 1104). A clock frequency for the first DAC and the second DAC may be two times a sampling frequency of the digital-to-analog conversion circuit.

The various operations of methods described above may be performed by any suitable means capable of performing the corresponding functions. The means may include various hardware component(s) and/or module(s), including, but not limited to one or more circuits. Generally, where there are operations illustrated in figures, those operations may have corresponding counterpart means-plus-function components with similar numbering. For example, means for receiving a digital input signal may include, for example, a DAC such as the DAC 400, a switch driver (e.g., the switch driver 404, 606, 904), a latch (e.g., latch 706 or 806) of a switch driver, and/or a data-change detection circuit 602, etc. Means for determining whether there is a digital transition in the digital input signal may include, for example, a data-change detection circuit 602, which may be implemented by an XOR logic gate (e.g., XOR logic gate 702), or a data encoder (e.g., the TX data processor 288). Means for gating a clock signal may include, for example, a clock-gating circuit 604, which may be implemented by an AND logic gate (e.g., AND logic gate 704). Means for converting may include, for example, a DAC such as the DAC 400, and more particularly, the current-steering cells 402 in the DAC.

### EXAMPLE ASPECTS

In addition to the various aspects described above, specific combinations of aspects are within the scope of the disclosure, some of which are detailed below:

Aspect 1: A digital-to-analog conversion circuit comprising: a detection circuit configured to detect digital transitions in a digital input signal; and a clock-gating circuit having an input coupled to an output of the detection circuit and configured to gate a clock signal for the digital-to-analog conversion circuit based on an output signal from the detection circuit.

Aspect 2: The digital-to-analog conversion circuit of Aspect 1, wherein the clock-gating circuit comprises an AND logic gate having a first input coupled to a clock signal node configured to receive the clock signal and having a second input coupled to the output of the detection circuit.

Aspect 3: The digital-to-analog conversion circuit of Aspect 1 or Aspect 2, further comprising a switch driver, wherein the detection circuit comprises an XOR logic gate having a first input coupled to a data output of the switch driver, having a second input coupled to a data input of the switch driver, and having an output coupled to the second input of the AND logic gate.

Aspect 4: The digital-to-analog conversion circuit of Aspect 1, further comprising a plurality of current-steering cells, each current-steering cell comprising a current-steering circuit and a switch driver coupled to the current-steering circuit, wherein a respective switch driver has a clock input coupled to an output of the clock-gating circuit.

Aspect 5: The digital-to-analog conversion circuit of Aspect 4, wherein the respective switch driver comprises a toggle flip-flop and wherein a data output of the toggle flip-flop is coupled to a data input of the toggle flip-flop.

Aspect 6: The digital-to-analog conversion circuit of Aspect 4, wherein the respective switch driver comprises a delay flip-flop, wherein a data output of the delay flip-flop is coupled to a first input of the detection circuit, wherein a data input of the delay flip-flop is coupled to a second input of the detection circuit.

Aspect 7: The digital-to-analog conversion circuit of Aspect 6, wherein the detection circuit comprises an XOR logic gate having a first input coupled to the data output of the delay flip-flop, having a second input coupled to the data input of the delay flip-flop, and having an output coupled to the input of the clock-gating circuit.

Aspect 8: The digital-to-analog conversion circuit of any of Aspects 4-7, wherein the clock-gating circuit is configured to allow the clock signal to clock the respective switch driver when a digital transition in the digital input signal is detected and to block the clock signal from clocking the respective switch driver when no digital transition in the digital input signal is detected, thereby reducing power consumption of the respective switch driver.

Aspect 9: The digital-to-analog conversion circuit of any of Aspects 1-8, wherein the digital-to-analog conversion circuit comprises an interleaved digital-to-analog conversion circuit comprising a first digital-to-analog converter (DAC) and a second DAC and wherein a clock frequency for the first DAC and the second DAC is two times a sampling frequency of the digital-to-analog conversion circuit.

Aspect 10: A wireless device comprising the digital-to-analog conversion circuit of any preceding Aspect, the wireless device further comprising: at least one antenna; and a transmit path coupled between an output of the digital-to-analog conversion circuit and the at least one antenna.

Aspect 11: A method for digital-to-analog conversion, comprising: receiving a digital input signal; determining whether there is a digital transition in the digital input signal; and gating a clock signal to a digital-to-analog conversion circuit based on the determination.

Aspect 12: The method of Aspect 11, wherein the digital-to-analog conversion circuit comprises a switch driver and wherein the method further comprises generating, via the switch driver, a digital output signal based on the digital input signal; determining whether there is a digital transition comprises comparing, via a first circuit, the digital input signal to the digital output signal; and gating the clock signal comprises blocking, via a second circuit, the clock signal from clocking the switch driver when the determination is that there is no digital transition in the digital input signal.

Aspect 13: The method of Aspect 12, wherein: the first circuit comprises an XOR logic gate having (i) a first input coupled to a data output of the switch driver and (ii) a second input coupled to a data input of the switch driver; and the second circuit comprises an AND logic gate having (i) a first input coupled to a clock signal node configured to receive the clock signal, (ii) a second input coupled to an output of the XOR logic gate, and (iii) an output coupled to a clock input of the switch driver.

Aspect 14: The method of Aspect 11, wherein the digital-to-analog conversion circuit comprises a plurality of current-steering cells, each current-steering cell comprising a current-steering circuit and a switch driver coupled to the current-steering circuit.

Aspect 15: The method of Aspect 14, wherein determining whether there is a digital transition in the digital input signal comprises comparing, via a first circuit, an input signal to the respective switch driver to an output signal from the respective switch driver.

Aspect 16: The method of Aspect 15, wherein: gating the clock signal comprises blocking, via a second circuit, the clock signal from clocking the respective switch driver when the determination is that there is no digital transition in the digital input signal; and an output of the second circuit is coupled to a clock input of the respective switch driver.

Aspect 17: The method of any of Aspects 14-16, further comprising allowing, via a second circuit, the clock signal to clock the respective switch driver when the determination is that there is a digital transition in the digital input signal.

Aspect 18: The method of any of Aspects 15-17, wherein: the first circuit comprises an XOR logic gate having (i) a first input coupled to a data output of the respective switch driver and (ii) a second input coupled to a data input of the respective switch driver; and the second circuit comprises an AND logic gate having (i) a first input coupled to a clock signal node configured to receive the clock signal, (ii) a second input coupled to an output of the XOR logic gate, and (iii) an output coupled to a clock input of the respective switch driver.

Aspect 19: The method of Aspect 18, wherein the XOR logic gate comprises a plurality of balanced transmission gates.

Aspect 20: The method of any of Aspects 14-19, wherein: the respective switch driver comprises a toggle flip-flop; and a data output of the toggle flip-flop is coupled to a data input of the toggle flip-flop.

Aspect 21: The method of any of Aspects 14-19, wherein the respective switch driver comprises a delay flip-flop or latch.

Aspect 22: The method of any of Aspects 11-21, wherein the digital-to-analog conversion circuit comprises an interleaved digital-to-analog conversion circuit comprising a first digital-to-analog converter (DAC) and a second DAC and wherein a clock frequency for the first DAC and the second DAC is two times a sampling frequency of the digital-to-analog conversion circuit.

Aspect 23: An apparatus for digital-to-analog conversion, comprising: means for receiving a digital input signal; means for determining whether there is a digital transition in the digital input signal; and means for gating a clock signal to the apparatus based on the determination.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another-even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. A digital-to-analog conversion circuit comprising:
a detection circuit configured to detect digital transitions in a digital input signal; and
a clock-gating circuit having an input coupled to an output of the detection circuit and configured to gate a clock signal for the digital-to-analog conversion circuit based on an output signal from the detection circuit.

2. The digital-to-analog conversion circuit of claim 1, wherein the clock-gating circuit comprises an AND logic gate having a first input coupled to a clock signal node configured to receive the clock signal and having a second input coupled to the output of the detection circuit.

3. The digital-to-analog conversion circuit of claim 2, further comprising a switch driver, wherein the detection circuit comprises an XOR logic gate having a first input coupled to a data output of the switch driver, having a second input coupled to a data input of the switch driver, and having an output coupled to the second input of the AND logic gate.

4. The digital-to-analog conversion circuit of claim 1, further comprising a plurality of current-steering cells, each current-steering cell comprising a current-steering circuit and a switch driver coupled to the current-steering circuit, wherein a respective switch driver has a clock input coupled to an output of the clock-gating circuit.

5. The digital-to-analog conversion circuit of claim 4, wherein the respective switch driver comprises a toggle flip-flop and wherein a data output of the toggle flip-flop is coupled to a data input of the toggle flip-flop.

6. The digital-to-analog conversion circuit of claim 4, wherein the respective switch driver comprises a delay flip-flop, wherein a data output of the delay flip-flop is coupled to a first input of the detection circuit, wherein a data input of the delay flip-flop is coupled to a second input of the detection circuit.

7. The digital-to-analog conversion circuit of claim 6, wherein the detection circuit comprises an XOR logic gate having a first input coupled to the data output of the delay flip-flop, having a second input coupled to the data input of the delay flip-flop, and having an output coupled to the input of the clock-gating circuit.

8. The digital-to-analog conversion circuit of claim 4, wherein the clock-gating circuit is configured to allow the clock signal to clock the respective switch driver when a digital transition in the digital input signal is detected and to block the clock signal from clocking the respective switch driver when no digital transition in the digital input signal is detected, thereby reducing power consumption of the respective switch driver.

9. The digital-to-analog conversion circuit of claim 1, wherein the digital-to-analog conversion circuit comprises an interleaved digital-to-analog conversion circuit comprising a first digital-to-analog converter (DAC) and a second DAC and wherein a clock frequency for the first DAC and the second DAC is two times a sampling frequency of the digital-to-analog conversion circuit.

10. A wireless device comprising the digital-to-analog conversion circuit of claim 1, the wireless device further comprising:
at least one antenna; and
a transmit path coupled between an output of the digital-to-analog conversion circuit and the at least one antenna.

11. A method for digital-to-analog conversion, comprising:
receiving a digital input signal;
determining whether there is a digital transition in the digital input signal; and
gating a clock signal to a digital-to-analog conversion circuit based on the determination.

12. The method of claim 11, wherein:
the digital-to-analog conversion circuit comprises a switch driver;
the method further comprises generating, via the switch driver, a digital output signal based on the digital input signal;
determining whether there is a digital transition comprises comparing, via a first circuit, the digital input signal to the digital output signal; and
gating the clock signal comprises blocking, via a second circuit, the clock signal from clocking the switch driver when the determination is that there is no digital transition in the digital input signal.

13. The method of claim 12, wherein:
the first circuit comprises an XOR logic gate having (i) a first input coupled to a data output of the switch driver and (ii) a second input coupled to a data input of the switch driver; and
the second circuit comprises an AND logic gate having (i) a first input coupled to a clock signal node configured to receive the clock signal, (ii) a second input coupled to an output of the XOR logic gate, and (iii) an output coupled to a clock input of the switch driver.

14. The method of claim 11, wherein the digital-to-analog conversion circuit comprises a plurality of current-steering cells, each current-steering cell comprising a current-steering circuit and a switch driver coupled to the current-steering circuit.

15. The method of claim 14, wherein determining whether there is a digital transition in the digital input signal comprises comparing, via a first circuit, an input signal to the respective switch driver to an output signal from the respective switch driver.

16. The method of claim 15, wherein:
gating the clock signal comprises blocking, via a second circuit, the clock signal from clocking the respective switch driver when the determination is that there is no digital transition in the digital input signal; and
an output of the second circuit is coupled to a clock input of the respective switch driver.

17. The method of claim 15, further comprising allowing, via a second circuit, the clock signal to clock the respective switch driver when the determination is that there is a digital transition in the digital input signal.

18. The method of claim 16, wherein:
the first circuit comprises an XOR logic gate having (i) a first input coupled to a data output of the respective switch driver and (ii) a second input coupled to a data input of the respective switch driver; and
the second circuit comprises an AND logic gate having (i) a first input coupled to a clock signal node configured to receive the clock signal, (ii) a second input coupled to an output of the XOR logic gate, and (iii) an output coupled to a clock input of the respective switch driver.

19. The method of claim 18, wherein the XOR logic gate comprises a plurality of balanced transmission gates.

20. The method of claim 14, wherein:
the respective switch driver comprises a toggle flip-flop; and
a data output of the toggle flip-flop is coupled to a data input of the toggle flip-flop.

21. The method of claim 14, wherein the respective switch driver comprises a delay flip-flop or latch.

22. The method of claim 11, wherein the digital-to-analog conversion circuit comprises an interleaved digital-to-analog conversion circuit comprising a first digital-to-analog converter (DAC) and a second DAC and wherein a clock frequency for the first DAC and the second DAC is two times a sampling frequency of the digital-to-analog conversion circuit.

23. An apparatus for digital-to-analog conversion, comprising:
means for receiving a digital input signal;
means for determining whether there is a digital transition in the digital input signal; and
means for gating a clock signal to the apparatus based on the determination.
